(19) United States
(12) Patent Application Publication
(10) Pub. No.: US 2009/0245114 A1
(43) Pub. Date: Oct. 1, 2009

(54) METHODS FOR COLLECTING AND ANALYZING NETWORK PERFORMANCE DATA

(76) Inventor: Jayanth VIJAYARAGHAVAN, Milpitas, CA (US)

Correspondence Address: HICKMAN PALERMO TRUONG & BECKER LLP/Yahoo! Inc., 2055 Gateway Place, Suite 550, San Jose, CA, 95110-1083, US

(21) Appl. No.: 12/060,619

(22) Filed: Apr. 1, 2008

(51) Int. Cl. G01R 31/08

(52) U.S. Cl. 370/241

(57) ABSTRACT

Techniques are described to collect and analyze network performance data. Servers are modified so connection data, including data re-transmitted, is stored on each server of a data center that serves data to clients. Each server then sends the connection data stored to a collection server that aggregates the data. The collection server sorts the connection data from the servers based upon the data center where the server is located and clusters of the location or routing of the client. The location of the client may be based on a geographic mapping of the client, routing by the autonomous system number, or an IP address prefix. A high rate of re-transmissions from a particular data center to a particular client location may indicate problems in a certain area of the network. The routing of data transmissions may be altered to a different data center or by assigning a different routing.

### FIELD OF THE INVENTION

The present invention relates to collecting and analyzing data related to network performance.

### BACKGROUND

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

As the importance of retrieving data from the Internet has increased, monitoring and analyzing how quickly and accurately the data may be transmitted has become paramount. For example, a user might wish to learn more about the topic “cars.” The user might commence his search by navigating to an Internet search engine website and then typing in the search query, “cars.” The request is routed to a server located in one of the data centers that serves the search application of the search engine. In response to the query, the server sends a response back to the client with a list of resources that may be visited that relate to the topic “cars.” When the response is received by the client computer, the data is displayed to the user. Though the user is only able to view the results displayed, how the request and response is routed in the network affects the user experience. For search engines or any other information provider, ensuring that users receive data quickly and accurately is one important aspect to provide a good user experience.

Data providers often own a large number of servers that provide identical content located in data centers to help provide data efficiently. As used herein, the term “data center” refers to a collection of associated servers. Should the data provider detect that there are any network anomalies or failures, requests to the data provider may be routed to either different servers within the data center, or a different data center entirely depending upon the nature of the failure.

The servers that belong to a particular data center are usually within the same building or complex but different data centers are often located geographically distant from each other. The geographic distance adds protection so that catastrophic failure in one data center caused by a natural disaster or other calamity would not also cause failure in the other data center. For example, one data center might be located on the East Coast in New York and another data center might be located on the West Coast in San Francisco. Thus, upon an earthquake in San Francisco that causes failure in that data center, requests may instead be routed to the data center in New York.

Separate data centers also allow large data providers to utilize the load of the servers more efficiently. For example, the data center in New York might have server loads of 85% indicating a large number of connections made to those servers. The data center in San Francisco might have server loads of 35% at that same instant. In order to utilize the server loads more evenly, any subsequent connection requests that previously would have been sent to the data center in New York would instead be routed to the data center in San Francisco until the server loads are equal.

Routing to various data centers or by various paths may also be determined by collecting information about network conditions and making adjustments based upon those conditions. For example, a network failure might occur at a single point in the network that causes all data packets traveling in that area of the network to not be forwarded to the data packets' destination. In another example, traffic congestion caused by too many data packets traveling in the same area of the network might cause network traffic to slow in that network area significantly. By identifying points of failure or congestion in a network, network routing may be adjusted so that network traffic may move as smoothly as possible. Thus, obtaining as much information as possible about the network and network performance has become increasingly important to large providers of data, such as search engines.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 is a block diagram displaying the relationship between the data centers, servers, clients, and collection server, according to an embodiment of the invention;

FIG. 2 is a diagram displaying the steps followed to collect and analyze network performance data, according to an embodiment of the invention; and

FIG. 3 is a block diagram of a computer system on which embodiments of the invention may be implemented.

### DETAILED DESCRIPTION

Techniques are described to collect and analyze data related to network performance. In the following description, for the purposes of explanation, numerous specific details are set forth in order to provide a thorough understanding of the present invention. It will be apparent, however, that the present invention may be practiced without these specific details. In other instances, well-known structures and devices are shown in block diagram form in order to avoid unnecessarily obscuring the present invention.

### General Overview

As used herein, “network performance data” is data that indicates the speed and performance of data transmission on a network. Network performance data may also indicate end user performance. Network performance data is based upon connection data between a server and client. Network performance data comprises the source IP address, the destination IP address, the source port, the data sent, the data re-transmitted, the data received, the maximum congestion window, the round trip time of a data packet, and any other measurement or metric that may be used to determine network performance. Among the factors that affect network performance are network traffic congestion, network failure, or router failure. By detecting difficulties in various parts of the network, routing may then be adjusted to ensure better network performance.

In an embodiment, servers are modified so that connection data is stored on each server of a data center that serves data to clients by a data provider. In order to detect network problems, the server is further modified to store data that is re-transmitted. In another embodiment, re-transmitted data is one factor of many (i.e., data latency, congestion) used to detect network problems. Each of the servers then sends the connection data to a collection server that aggregates the data. Aggregating the number of transmitted and re-transmitted data packets and determining the origin and destination of the data packets helps determine areas of the network where congestions or other problems may be occurring and routing may then be altered in response to the network.

In an embodiment, the collection server sorts the connection data from the servers based upon the data center where the server is located and the location of the client. The location of the client may be based on a geographic mapping of the client, an Autonomous System number, or an IP address range. The Autonomous System number is a number that indicates routing. IP address ranges may vary. For example, the IP address range might be a large range with potentially many users or a short range, indicating more granularity.

In an embodiment, the sorted data is able to be analyzed based upon the data center and the location of the client. A high rate of re-transmissions from a particular data center to a particular client location may indicate problems in a certain area of the network. The routing of data transmissions may then be altered to a different data center or by assigning a different route.

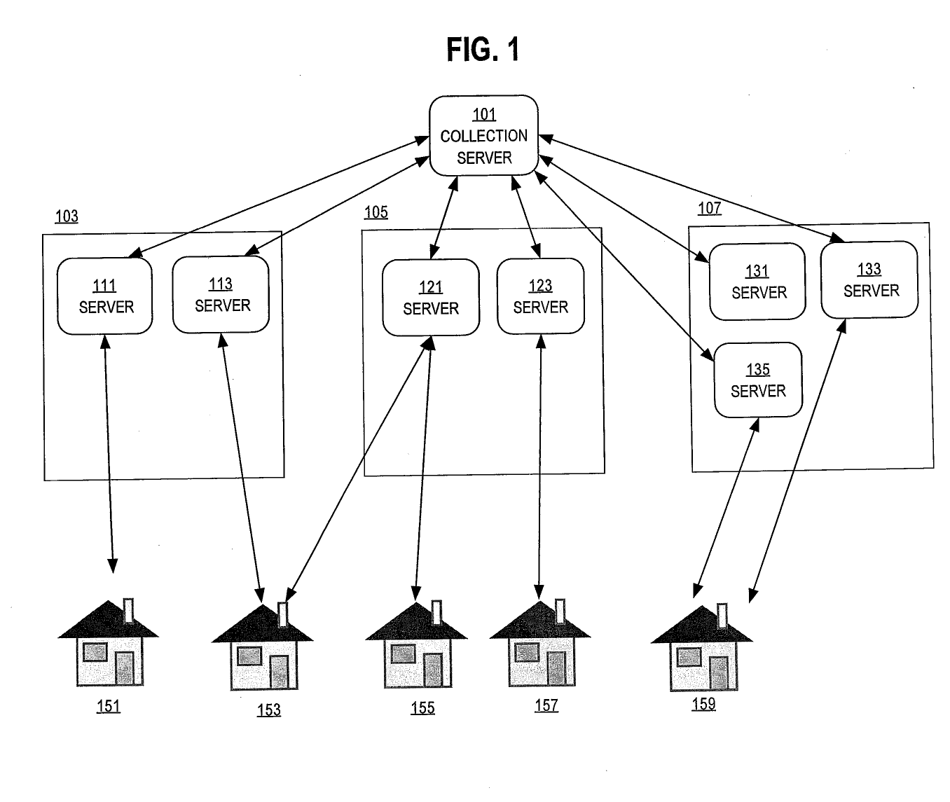

A block diagram displaying how the servers, data centers, collection servers, and clients interact, according to an embodiment, is shown in FIG. 1. In FIG. 1, there are three data centers, data center 103, data center 105, and data center 107. Data center 103 comprises two servers. The number of servers located in each data center will vary widely from implementation to implementation. Server 111 and server 113 are located in data center 103. Data center 105 also comprises two servers. Server 121 and server 123 are located in data center 105. Data center 107 comprises three servers. Server 131, server 133, and server 135 are located in data center 107.

Each of the servers connect to clients. Clients are shown as client 151, client 153, client 155, client 157, and client 159. The servers are modified to store connection data, including re-transmission data, when the server connects with a client. The connection data is sent to a collection server 101 that also collects data from all other available servers. At the collection server, the connection data received is aggregated with connection data from other servers. The collection server then sorts the connection data based upon the data center where the server is located and the actual location or routing assigned for a client. From this information, decisions to change routings or to further review network problems may be made.

### Storing Network Performance Data in a Server

In an embodiment, servers are modified so that connection data is stored on each server of a data center that serves data to clients by a data provider. The server is further modified to store data that is re-transmitted. Data transmissions may follow any type of data transmission protocol, including TCP. The Transmission Control Protocol (“TCP”) is an Internet protocol that allows applications on a networked host to create a connection to another host. For example, a client requesting a web page might represent one host and the server providing the web page content to the client might represent the other host.

The TCP protocol has many properties related to the connection between hosts. TCP guarantees reliable and in-order delivery of data from a sender to the receiver. In order to accomplish in-order delivery, TCP also provides for retransmitting lost packets and discarding duplicate packets sent. TCP is also able to distinguish data for multiple connections by concurrent applications (e.g., a web server and e-mail server) running on the same host.

To initiate a TCP connection, the initiating host sends a synchronization (SYN) packet to initiate a connection with an initial sequence number. The initial sequence number identifies the order of the bytes sent from each host so that the data transferred remains in order regardless of any fragmentation or disordering that might occur during a transmission. For every byte transmitted, the sequence number is incremented. Each byte sent is assigned a sequence number by the sender and then the receiver sends an acknowledgement (ACK) back to the sender to confirm the transmission.

For example, if computer A (the server) sends 4 bytes with a sequence number of 50 (the four bytes in the packet having sequence numbers of 50, 51, 52, and 53 assigned), then computer B (the client) would send back to computer A an acknowledgement of 54 to indicate the next byte computer B expects to receive. By sending an acknowledgement of 54, computer B is signaling that bytes 50, 51, 52, and 53 were correctly received. If, by some chance, the last two bytes were corrupted then computer B sends an acknowledgement value of 52 because bytes 50 and 51 were received successfully. Computer A would then re-transmit to computer B data packets beginning with sequence number 52.

In an embodiment, each server within all data centers is modified to store connection data from the server to any client. The modifications may be implemented by changing the kernel of the server to store connection data based upon a TCP connection. In an embodiment, the kernel is modified to record all TCP connection flows including re-transmitted bytes per connection, round trip times of SYN packet, total bytes transmitted, and total throughput per connection.

As used herein, “connection data” refers to any measurement, metric, or data used in a network connection. Some examples of connection data include, but are not limited to, source IP address, source port, destination IP address, destination port, data sent, data re-transmitted, data received, duplicate data received, maximum congestion window, SYN round-trip time, smooth round-trip time, and any other data or measurement for a network connection. The connection data may be stored in any format. In an embodiment, the connection data is stored in the format: source IP address, source port, destination IP address, destination port, data sent, data re-transmitted, data received, duplicate data received, maximum congestion window, SYN round-trip time, and smooth round-trip time. Data re-transmitted indicates occurrences when data re-transmissions occurred from the server. Duplicate data received indicates occurrences when data re-transmissions occurred from the client.

The connection data may also add functionality by storing more information. For example, the connection data might also store more granular response times when a connection is made. In an embodiment, rather than storing only round trip times, the time elapsed for a server to send a complete request, the elapsed time for a server to send an acknowledgement after receiving a client request, and the elapsed time for a client to send a request is also stored. These finer grained times allow more precision when determining the throughput or speed of the data transmission after the data has left the server.

The SYN round trip time is the elapsed time between the transmission of a SYN packet and the receipt of an acknowledgement. The smooth round trip time is the elapsed time between the transmission of a packet to a neighbor and the receipt of an acknowledgement. The smooth round trip time indicates the speed of the link or links along a path to a particular neighbor. The elapsed time may be measured in any time interval, such as milliseconds.

In an embodiment, the connection data is stored as a raw log, or a log file without any formatting. In an embodiment, the connection data is stored at the server for a time, before periodically being sent to a collection server. In another embodiment, the connection data is sent to the collection server continuously, as the data is being recorded by the server.

In an embodiment, a collection server receives the connection data from each of the servers. The collection server aggregates the data from each of the servers and sorts the connection data from the servers based upon the data center where the server is located and then by a cluster indicating the location the client. The clustering may be based on a geographic mapping of the client, by the autonomous system number, or by an IP address prefix of a variable length.

### Clustering by Geographic Mapping

Geographic mapping of a client may occur through geolocation. As used herein, geolocation refers to identifying the real-world geographic location of an Internet connected computer or device. Geolocation may be performed by associating a geographic location with an IP address, MAC address, Wi-Fi connection location, GPS coordinates, or any other identifying information. In an embodiment, when a particular IP address is recorded, the organization and physical address listed as the owner of that particular IP address is found and then mapped from the location to the particular IP address. For example, the server has recorded a destination IP address of 1.2.3.4. The IP address is queried to determine that the address is included in a block of IP addresses owned by ACME Company that has headquarters in San Francisco. Though there is no absolute certainty that the client at the IP address 1.2.3.4 is physically located in San Francisco (because a proxy server may be used), the likelihood is high that most connections made with the IP address 1.2.3.4 are in San Francisco. Other methods such as tracing network gateways and router locations may also be employed.

In an embodiment, IP addresses are mapped by the collection server to geographic locations based upon clusters from geolocation data aggregators. There are many geolocation data aggregators, such as Quova, located in Mountain View, Calif., that determine physical location based upon IP address location as well as other methods. A number of IP addresses are clustered into groups based upon physical locations. In an embodiment, the physical locations may vary in granularity. For example, there might be an instance where a cluster may be geolocated by city and state. In another instance, a cluster may be geolocated by a region, such as the northeastern United States. In another instance, a cluster may be geolocated by country.

### Clustering by Autonomous System Number and IP Address Prefix

In an embodiment, aggregated data is sorted by the collection server based upon the data center of a server and a cluster based upon an autonomous system number. An autonomous system number is a number that is allocated to an autonomous system for use in BGP routing and indicates the routing to be used for data transmission.

The Border Gateway Protocol (“BGP”) is the core routing protocol of the Internet. BGP works by maintaining routing tables of IP networks or “prefixes” that designate the ability to reach a network. The information in a routing table may include, but is not limited to, the IP address of the destination network, the time needed to travel the path through which the packet is to be sent, and the address of the next station to which the packet is to be sent on the way to destination, also called the “next hop.” BGP makes routing decisions based on available paths and network policies. For example, if there are two paths available to the same destination, routing may be determined by selecting the path allows a packet to reach the destination fastest. This returns the “closest” route.

As used herein, an autonomous system is a group of IP networks operated by one or more network operators that has a single, clearly defined external routing policy. An autonomous system has a globally unique autonomous system number that is used to exchange exterior routing information between neighboring autonomous systems and as an identifier of the autonomous system itself.

In another embodiment, aggregated data is sorted by the collection server based upon the data center of a server and a cluster based upon an IP address prefix of variable length. For example, aggregated data might be clustered based upon an IP address prefix of 1.2.3.x wherein all of the items clustered begin with the IP address “1.2.3” with any number between 0 and 255 taking the place of the “x”. This limits the granularity of the IP range to 256 possible combinations. In another example, the granularity of the IP address prefix might be much more course such as 1.2.y.x. In this example, all IP address that begin “1.2” would be included in the cluster with a value of 0 to 255 for “y” and 0 to 255 for “x” with 65,536 (256²) combinations. Because more possible IP addresses may be clustered, the granularity is less.

### Analyzing the Stored Data

The aggregated and sorted connection data is stored in the collection server and then used to analyze network performance. The aggregated and sorted data is stored in such a format, that the network performance may be analyzed based upon a particular data center. In an embodiment, for each particular data center, a cluster of the geolocation of IP addresses or an autonomous system number based upon BGP is stored. If the data center and geolocation of IP addresses is stored, then network performance from the data center to a particular geographic location may be determined. For example, the re-transmission rate from data center 1 might be extremely high to the city of New York but moderate to all other cities along the East Coast of the United States. From this information, a network problem is determined when data is transmitted from Data Center 1 to clients in New York. The data provider may contact the Internet Service Provider serving New York that there may be a problem or data traffic may be routed in a different fashion to New York.

In another embodiment, rather than relying only upon re-transmission rates, other factors are considered in order to determine network performance. For example, the round trip time, or latency of data, might be considered along with re-transmission in order to determine network problems. In yet another embodiment, data other than re-transmission rates are the only factors considered to detect network problems. For example, network problems might be based only upon round trip times of data packets.

If the data center and autonomous system numbers from BGP are stored, then network performance from the data center following a particular routing path may be determined. For example, the re-transmission rate from data center 1 might be extremely high following a particular path. The data provider may select not to transmit data subsequently on the routing with the high re-transmission rate and instead select another routing with less errors.

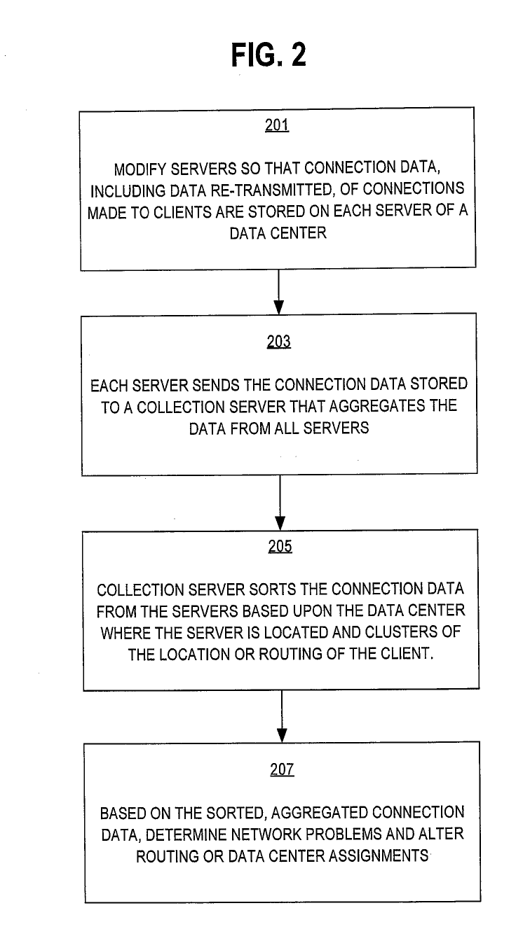

An illustration of steps taken to collect and analyze network performance data, according to an embodiment, is shown in FIG. 2. In step 201, the servers are modified by a system administrator or programmer so that connection data that shows the connections made from the servers to clients are stored. Included in the connection data are re-transmitted data packets. In step 203, each server sends the connection data stored to a collection server. The collection server collects the connection data and then aggregates the connection data from all of the servers. As shown in step 205, the collection server then sorts the connection data from the servers. The connection data is sorted based upon the data centers where the servers are located and clusters of the location or routings of the client. The location may be any physical real-world location and the routing may be identified by an autonomous system number. Finally, in step 207, based upon the sorted and aggregated connection data at the collection server, network problems and trouble spots may be detected using re-transmission data as an indicator. High rates of re-transmission at particular areas of the network indicate a high likelihood of problems. As a result of the analysis, subsequent connections made to clients may be made from a different data center or use alternate routing in order to avoid network problem areas.

Having more accurate network performance data also allows the ability to decide where to place or locate data centers in order to be most effective. For example, data may be served from colocation 1 and colocation 2 within a given country. After performing measurements of network performance, the network performance data indicates that colocation 1 and colocation 2 have a high re-transmission rate to majority of users. Another set of colocations might also be serving the same users from another country or location. If network performance data indicates that the re-transmission rate for the set of colocations from another country or location is smaller, the location of the data center might to moved to the other country or new colocation. In other words, more accurate network performance data enables a more informed choice in order to select data providers that exhibit the best performance in terms of re-transmissions or any other network performance metric that may be analyzed.

### Hardware Overview

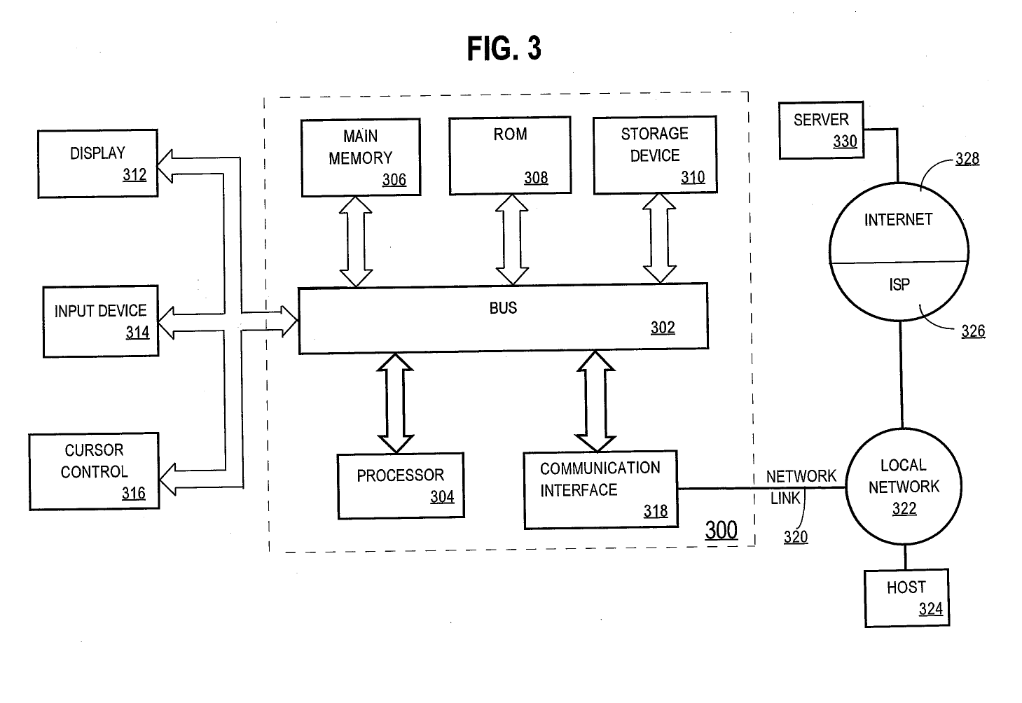

FIG. 3 is a block diagram that illustrates a computer system 300 upon which an embodiment of the invention may be implemented. Computer system 300 includes a bus 302 or other communication mechanism for communicating information, and a processor 304 coupled with bus 302 for processing information. Computer system 300 also includes a main memory 306, such as a random access memory (RAM) or other dynamic storage device, coupled to bus 302 for storing information and instructions to be executed by processor 304. Main memory 306 also may be used for storing temporary variables or other intermediate information during execution of instructions to be executed by processor 304. Computer system 300 further includes a read only memory (ROM) 308 or other static storage device coupled to bus 302 for storing static information and instructions for processor 304. A storage device 310, such as a magnetic disk or optical disk, is provided and coupled to bus 302 for storing information and instructions.

Computer system 300 may be coupled via bus 302 to a display 312, such as a cathode ray tube (CRT), for displaying information to a computer user. An input device 314, including alphanumeric and other keys, is coupled to bus 302 for communicating information and command selections to processor 304. Another type of user input device is cursor control 316, such as a mouse, a trackball, or cursor direction keys for communicating direction information and command selections to processor 304 and for controlling cursor movement on display 312. This input device typically has two degrees of freedom in two axes, a first axis (e.g., x) and a second axis (e.g., y), that allows the device to specify positions in a plane.

The invention is related to the use of computer system 300 for implementing the techniques described herein. According to one embodiment of the invention, those techniques are performed by computer system 300 in response to processor 304 executing one or more sequences of one or more instructions contained in main memory 306. Such instructions may be read into main memory 306 from another machine-readable medium, such as storage device 310. Execution of the sequences of instructions contained in main memory 306 causes processor 304 to perform the process steps described herein. In alternative embodiments, hard-wired circuitry may be used in place of or in combination with software instructions to implement the invention. Thus, embodiments of the invention are not limited to any specific combination of hardware circuitry and software.

The term “machine-readable medium” as used herein refers to any medium that participates in providing data that causes a machine to operation in a specific fashion. In an embodiment implemented using computer system 300, various machine-readable media are involved, for example, in providing instructions to processor 304 for execution. Such a medium may take many forms, including but not limited to storage media and transmission media. Storage media includes both non-volatile media and volatile media. Non-volatile media includes, for example, optical or magnetic disks, such as storage device 310. Volatile media includes dynamic memory, such as main memory 306. Transmission media includes coaxial cables, copper wire and fiber optics, including the wires that comprise bus 302. Transmission media can also take the form of acoustic or light waves, such as those generated during radio-wave and infra-red data communications. All such media must be tangible to enable the instructions carried by the media to be detected by a physical mechanism that reads the instructions into a machine.

Common forms of machine-readable media include, for example, a floppy disk, a flexible disk, hard disk, magnetic tape, or any other magnetic medium, a CD-ROM, any other optical medium, punchcards, papertape, any other physical medium with patterns of holes, a RAM, a PROM, and EPROM, a FLASH-EPROM, any other memory chip or cartridge, a carrier wave as described hereinafter, or any other medium from which a computer can read.

Various forms of machine-readable media may be involved in carrying one or more sequences of one or more instructions to processor 304 for execution. For example, the instructions may initially be carried on a magnetic disk of a remote computer. The remote computer can load the instructions into its dynamic memory and send the instructions over a telephone line using a modem. A modem local to computer system 300 can receive the data on the telephone line and use an infra-red transmitter to convert the data to an infra-red signal. An infra-red detector can receive the data carried in the infra-red signal and appropriate circuitry can place the data on bus 302. Bus 302 carries the data to main memory 306, from which processor 304 retrieves and executes the instructions. The instructions received by main memory 306 may optionally be stored on storage device 310 either before or after execution by processor 304.

Computer system 300 also includes a communication interface 318 coupled to bus 302. Communication interface 318 provides a two-way data communication coupling to a network link 320 that is connected to a local network 322. For example, communication interface 318 may be an integrated services digital network (ISDN) card or a modem to provide a data communication connection to a corresponding type of telephone line. As another example, communication interface 318 may be a local area network (LAN) card to provide a data communication connection to a compatible LAN. Wireless links may also be implemented. In any such implementation, communication interface 318 sends and receives electrical, electromagnetic or optical signals that carry digital data streams representing various types of information.

Network link 320 typically provides data communication through one or more networks to other data devices. For example, network link 320 may provide a connection through local network 322 to a host computer 324 or to data equipment operated by an Internet Service Provider (ISP) 326. ISP 326 in turn provides data communication services through the world wide packet data communication network now commonly referred to as the “Internet” 328. Local network 322 and Internet 328 both use electrical, electromagnetic or optical signals that carry digital data streams. The signals through the various networks and the signals on network link 320 and through communication interface 318, which carry the digital data to and from computer system 300, are exemplary forms of carrier waves transporting the information.

Computer system 300 can send messages and receive data, including program code, through the network(s), network link 320 and communication interface 318. In the Internet example, a server 330 might transmit a requested code for an application program through Internet 328, ISP 326, local network 322 and communication interface 318.

The received code may be executed by processor 304 as it is received, and/or stored in storage device 310, or other non-volatile storage for later execution. In this manner, computer system 300 may obtain application code in the form of a carrier wave. In the foregoing specification, embodiments of the invention have been described with reference to numerous specific details that may vary from implementation to implementation. Thus, the sole and exclusive indicator of what is the invention, and is intended by the applicants to be the invention, is the set of claims that issue from this application, in the specific form in which such claims issue, including any subsequent correction. Any definitions expressly set forth herein for terms contained in such claims shall govern the meaning of such terms as used in the claims. Hence, no limitation, element, property, feature, advantage or attribute that is not expressly recited in a claim should limit the scope of such claim in any way. The specification and drawings are, accordingly, to be regarded in an illustrative rather than a restrictive sense.

What is claimed is:

1. A method to collect network performance data, comprising:
receiving, from a plurality of servers, connection data based upon transmissions of data packets sent and received by the plurality of servers and a client, of a plurality of clients, wherein each of the plurality of servers are located in a particular data center, of a plurality of data centers;
aggregating the connection data from the plurality of servers;
sorting the aggregated connection data based upon the data center where the server is located and a cluster associated with the client; and
upon sorting the aggregated connection data based upon the data center and the cluster associated with the client, storing the sorted, aggregated connection data.

2. The method of claim 1, wherein aggregated connection data comprises a quantity of data packets sent, a quantity of re-transmitted data packets sent, a quantity of data packets received, a quantity of re-transmitted data packets received, and round trip times of data packets.

3. The method of claim 1, wherein the cluster associated with the client comprises a geographic location to which an IP address of the client is mapped.

4. The method of claim 3, wherein the geographic location is a city.

5. The method of claim 3, wherein the geographic location is a country.

6. The method of claim 1, wherein the cluster associated with the client comprises an identifier of a routing to which an IP address of the client is associated.

7. The method of claim 6, wherein the identifier of the routing is an autonomous system number.

8. The method of claim 2, wherein aggregated connection data further comprises an application that the server provides.

9. The method of claim 8, wherein the connection data is received from the plurality of servers continuously.

10. A system to collect network performance data, comprising:
a plurality of servers, wherein each server is located in a particular data center of a plurality of data centers;
a collection server; and
a plurality of clients;
wherein the plurality of servers store connection data based upon transmissions of data packets sent and received by the plurality of servers and a client, of the plurality of clients;
the plurality of servers send connection data to the collection server;
the collection server aggregates the connection data;
the collection server sorts the aggregated connection data based upon the data center where the server is located and a cluster associated with the client;
upon sorting the aggregated connection data based upon the data center and the cluster associated with the client, the collection server storing the sorted, aggregated connection data.

11. The system of claim 10, wherein aggregated connection data comprises a quantity of data packets sent, a quantity of re-transmitted data packets sent, a quantity of data packets received, a quantity of re-transmitted data packets received, and round trip times of data packets.

12. The system of claim 10, wherein the cluster associated with the client comprises a geographic location to which an IP address of the client is mapped.

13. The system of claim 10, wherein the cluster associated with the client comprises an identifier of a routing to which an IP address of the client is associated.

14. The system of claim 10, wherein the identifier of the routing is an autonomous system number.

15. A computer-readable storage medium carrying one or more sequences of instructions which, when executed by one or more processors, causes the one or more processors to:
receive, from a plurality of servers, connection data based upon transmissions of data packets sent and received by the plurality of servers and a client, of a plurality of clients, wherein each of the plurality of servers are located in a particular data center, of a plurality of data centers;
aggregate the connection data from the plurality of servers;
sort the aggregated connection data based upon the data center where the server is located and a cluster associated with the client; and
upon sorting the aggregated connection data based upon the data center and the cluster associated with the client, store the sorted, aggregated connection data.

16. The computer-readable storage medium of claim 15, wherein aggregated connection data comprises a quantity of data packets sent, a quantity of re-transmitted data packets sent, a quantity of data packets received, a quantity of re-transmitted data packets received, and round trip times of data packets.

17. The computer-readable storage medium of claim 15, wherein the cluster associated with the client comprises a geographic location to which an IP address of the client is mapped.

18. The computer-readable storage medium of claim 16, wherein the geographic location is a city.

19. The computer-readable storage medium of claim 16, wherein the geographic location is a country.

20. The computer-readable storage medium of claim 15, wherein the cluster associated with the client comprises an autonomous system number to which an IP address of the client is associated.

21. The computer-readable storage medium of claim 15, wherein the connection data is received from the plurality of servers continuously.

22. The computer-readable storage medium of claim 16, wherein aggregated connection data further comprises an application that the server provides.
